(19) United States
(12) Patent Application Publication
(10) Pub. No.: US 2026/0287636 A1
(43) Pub. Date: Sep. 24, 2026

(54) INSULATION MONITORING DEVICE (IMD), SYSTEM FOR MONITORING INSULATION AND METHOD FOR MONITORING INSULATION OF IMD

(71) Applicant: LS ELECTRIC CO., LTD., Anyang-si (KR)

(72) Inventors: Changjun KIM, Anyang-si (KR); Minsu PARK, Anyang-si (KR)

(21) Appl. No.: 19/553,572

(22) Filed: Mar. 2, 2026

(30) Foreign Application Priority Data
Mar. 18, 2025 (KR) 10-2025-0034878

(51) Int. Cl. G01R 31/14; H02H 7/20

(52) U.S. Cl. CPC G01R 31/14; H02H 7/20

(57) ABSTRACT

Provided is an insulation monitoring device, an insulation monitoring system, and an insulation monitoring method, in which insulation of one of a first zone and a second zone is monitored through selective connection to one of an electric path of the first zone between a transformer and a first power conversion device and an electric path of the second zone between the transformer and a second power conversion device according to whether the power conversion device is in operation.

### CROSS-REFERENCE TO RELATED APPLICATION

Pursuant to 35 USC § 119(a), this application claims the benefit of the earlier filing date and the right of priority to Korean Patent Application No. 10- 2025-0034878, filed on Mar. 18, 2025, the contents of which are incorporated by reference herein in its entirety.

### FIELD

The disclosure relates to an insulation monitoring device (IMD) that monitors the insulation of a system including a power conversion device.

### BACKGROUND

The technology that forms the background of the disclosure relates to monitoring the insulation of an ungrounded system.

Isolated terra (IT) grounding is a method in which any of power lines is not grounded and grounding is achieved only through an enclosure of a load. The IT grounding method has the advantage of ensuring a continuous operation of a system because there is time to find a site where a ground fault has occurred without stopping the operation of the system even when the ground fault occurs in any one of power lines.

However, the system can be operated even when the ground fault occurs, and thus it is necessary to continuously monitor the insulation status of the power lines even when the system is in operation. In an ungrounded system, an extremely low fault current flows during a ground fault. It is difficult to detect such fault current using a ground fault detection device which is used in a grounded system. In AC systems, ground potential transformers (GPTs) have been used to measure zero-sequence voltage. However, GPT cannot be applied to DC lines, such as those in solar power and energy storage system (ESS). Insulation monitoring devices (IMDs) have been adopted as an alternative for ungrounded systems, as shown in FIG. 1.

The IMD is a device as disclosed in Korean Patent Application Publication No. 10-2024-0147294 (published on Oct. 8, 2024, hereinafter referred to as "Prior Art Document"). The IMD may include a pulse signal generator that is arranged between a ground and a transmission line, forms a circuit between the transmission line and the ground through insulation resistance, which is formed between the transmission line and the ground, and injects a square wave (pulse) signal into the formed circuit, and a detection resistor that detects a voltage according to the square wave signal. When the pulse signal generator applies a signal (voltage Vp) to the ground (protective earth PE), insulation resistance Re is calculated based on a signal (voltage Vm) in which the voltage is distributed by virtual resistance (insulation resistance Re) between an ungrounded line and the ground from the applied signal Vp and internal resistance Ri of the IMD, thereby enabling the insulation status of the ungrounded line to be monitored.

In recent times, as the penetration rate of renewable energy increases, there is a trend toward building power grids to manage loads and stabilize renewable energy. As part of this trend, energy storage devices (ESS) are being installed in the power grids. The ESS can efficiently and stably supply power to loads by storing excessively generated power and discharging the stored power when there is an energy shortage in the power grids.

As an ESS is installed in a power grid, the ESS is connected to an ungrounded line through which alternating current (AC) supplied from a power source flows. In this case, a line section from the power source to the ESS may be connected to a line section connecting a power conditioning system (PCS) arranged in the ESS to a battery.

When a power system including the PCS, such as an ESS system, is connected to an ungrounded system, only one IMD should operate per system. When several IMDs are installed on the same line, an insulation resistance value measured by each IMD is expressed as a combined resistance value of insulation resistance between an actual line to be measured and the ground and internal resistance of other installed IMDs, which makes accurate measurement impossible. Furthermore, when a plurality of IMDs performs the measurement at the same time, normal measurement operation is not allowed due to interference between the measurement waveforms transmitted from a signal generator of each IMD to the PE for measurement. Therefore, as shown in FIG. 2, the IMD must be installed on each of AC side and DC side which are the front and rear ends of the PCS. In this case, a coupler (coupling device) is utilized for voltage expansion on the DC side corresponding to DC power. When operating at a higher voltage than the IMD unit alone, such a coupler is further installed.

In this way, when the IMD is installed, the measurement range of the system in which the IMD is installed changes depending on whether the PCS is in operation. As shown in FIG. 2, when the PCS is not in operation, the AC side and DC side systems are separated, and the IMDs on the AC side (monitoring range 1) and the DC side (monitoring range 2) each monitor insulation. As shown in FIG. 3, when the PCS is in operation, the AC side and DC side become the same system, and one IMD on the DC side monitors insulation.

Meanwhile, in the case of a multi-winding transformer, a plurality of systems may be connected as shown in FIG. 4. In this case, IMDs are installed on the AC side and DC side of a first system and the AC side and DC side of a second system, respectively, so that a total of four IMDs are required.

As such, IMDs had to be installed on the AC side and DC side of the system, but this large number of installations increased installation costs and inconvenience, and there was a limitation that installation space was insufficient. In particular, when the PCS is in operation, the IMD on the AC side does not work, raising concerns about the necessity and efficiency of installing the IMDs throughout an entire zone of the system.

### SUMMARY

The disclosure aims to overcome the aforementioned limitations of the related art.

Accordingly, an aspect of the disclosure is to provide an embodiment capable of reducing the number of IMDs arranged in a system.

Another aspect of the disclosure is to provide an embodiment capable of performing insulation monitoring on a plurality of AC sides while reducing the number of IMDs.

Another aspect of the disclosure, which aims to solve the above-described problem, is to monitor insulation of one system through an IMD of another system.

More specifically, an aspect of the disclosure is to arrange a coupler, other than an IMD, on an AC side of the other system, such that an IMD on an AC side of one system monitors insulation of the AC side of the other system by utilizing the coupler.

Such technical features can be applied to and implemented in insulation monitoring devices, insulation monitoring systems, power systems, power conversion systems, and insulation monitoring methods, and this specification aims to provide embodiments of insulation monitoring devices, insulation monitoring systems, and insulation monitoring methods that use the above technical features as a means for solving the relevant problems.

An embodiment of the insulation monitoring device, which is an insulation monitoring device configured to monitor insulation of a plurality of systems connected to a multi-winding transformer, includes a first channel unit connected to an electric path of a first zone between the multi-winding transformer and a first power conversion device in a first system, a second channel unit connected to a coupling device connected to an electric path of a second zone between the multi-winding transformer and a second power conversion device in a second system, and a monitoring unit connected to a ground that is not connected to an electric path of the first system, connected to one of the first channel unit and the second channel unit according to an operation signal transmitted from at least one of the first power conversion device and the second power conversion device, and configured to apply a predetermined signal to one of the ground and a connected channel unit, receive a measurement signal corresponding to the predetermined signal from another channel unit, and determine an insulation status of a zone corresponding to the connected channel unit based on the measurement signal.

In an embodiment of the insulation monitoring device, a first protection device may be arranged in the first zone to connect or disconnect the multi-winding transformer to or from the first power conversion device, and the first channel unit may be connected to an electric path between the multi-winding transformer and the first protection device.

In an embodiment of the insulation monitoring device, one of the first channel unit and the second channel unit may be connected to the monitoring unit while the first protection device is open.

In an embodiment of the insulation monitoring device, a second protection device may be arranged in the second zone to connect or disconnect the multi-winding transformer to or from the second power conversion device, and the second channel unit may be connected to an electric path between the multi-winding transformer and the second protection device.

In an embodiment of the insulation monitoring device, one of the first channel unit and the second channel unit may be connected to the monitoring unit while the second protection device is open.

In an embodiment of the insulation monitoring device, the first channel unit and the second channel unit may be disconnected from the monitoring unit in a state where a first protection device arranged in the first zone to connect or disconnect the multi-winding transformer to or from the first power conversion device and a second protection device arranged in the second zone to connect or disconnect the multi-winding transformer to or from the second power conversion device are closed.

In an embodiment of the insulation monitoring device, the monitoring unit may be connected to the first channel unit to determine an insulation status of the first zone based on the measurement signal received from the ground or the first channel unit when receiving a first operation signal from at least one of the first power conversion device and the second power conversion device, and connected to the second channel unit to determine an insulation status of the second zone based on the measurement signal received from the ground or the second channel unit when a second operation signal is received from at least one of the first power conversion device and the second power conversion device.

In an embodiment of the insulation monitoring device, the monitoring unit may calculate magnitude of insulation resistance of a zone corresponding to the connected channel unit based on the measurement signal, and determine an insulation status of the zone corresponding to the connected channel unit based on the magnitude of the insulation resistance.

An embodiment of the insulation monitoring system includes a multi-winding transformer configured to transmit a three-phase alternating current (AC) voltage, a first power conversion device installed in a first system, and configured to receive the AC voltage from the multi-winding transformer and convert the AC voltage into a direct current (DC) voltage, a second power conversion device installed in a second system, and configured to receive the AC voltage from the multi-winding transformer and convert the AC voltage into a DC voltage, a first insulation monitoring device configured to monitor insulation of a first electric path as a primary side of the first power conversion device, a coupling device configured to receive a signal from a second electric path as a primary side of the second power conversion device, a second insulation monitoring device configured to monitor insulation of a first load-side electric path receiving the DC voltage from the first power conversion device, and a third insulation monitoring device configured to monitor insulation of a second load-side electric path receiving the DC voltage from the second power conversion device, wherein the first insulation monitoring device includes a first channel unit configured to receive a signal from the first electric path, a second channel unit configured to receive a signal, which is received from the second electric path, from the coupling device, a signal unit configured to apply a predetermined signal to a ground not connected to the first system and the second system, a control unit connected to one of the first channel unit and the second channel unit, and configured to receive a measurement signal corresponding to the predetermined signal from a connected channel unit, and determine an insulation status of an electric path corresponding to the connected channel unit based on the measurement signal, and a connecting unit configured to connect the first channel unit to the control unit when monitoring the first electric path, and connect the second channel unit to the control unit when monitoring the second electric path.

In an embodiment of the insulation monitoring system, the insulation monitoring system may further include a first protection device configured to connect or disconnect the multi-winding transformer to or from the first power conversion device, and a second protection device configured to connect or disconnect the multi-winding transformer to or from the second power conversion device, wherein the first insulation monitoring device may be connected to an electric path between the multi-winding transformer and the first protection device, and the coupling device may be connected to an electric path between the multi-winding transformer and the second protection device.

In an embodiment of the insulation monitoring system, the connecting unit may disconnect the first channel unit and the second channel unit from the control unit when the first protection device connects the multi-winding transformer to the first power conversion device and the second protection device connects the multi-winding transformer to the second power conversion device.

In an embodiment of the insulation monitoring system, the connecting unit may include a first switching portion configured to connect the first channel unit to the control unit when monitoring the first electric path, and disconnect the first channel unit from the control unit when monitoring the second electric path, the first load-side electric path, or the second load-side electric path, and a second switching portion configured to connect the second channel unit to the control unit when monitoring the second electric path, and disconnect the second channel unit from the control unit when monitoring the first electric path, the first load-side electric path, or the second load-side electric path.

An embodiment of the insulation monitoring method, which is an insulation monitoring method of an insulation monitoring device including a first channel unit configured to receive a signal from a first electric path between a multi-winding transformer and a first power conversion device, a second channel unit configured to receive a signal from a coupling device that receives a signal from a second electric path between the multi-winding transformer and a second power conversion device, and a monitoring unit configured to monitor an insulation status of one of the first electric path and the second electric path based on a signal received from one of the first channel unit and the second channel unit by applying a predetermined signal to a ground, to which the first electric path and the second electric path are not connected, includes deciding a monitoring mode of the insulation monitoring device, connecting to one of the first channel unit and the second channel unit according to the monitoring mode, applying the predetermined signal to the ground to receive a measurement signal corresponding to the predetermined signal from a connected channel unit, and determining an insulation status of an electric path connected to the connected channel unit based on the measurement signal.

In an embodiment of the insulation monitoring method, the monitoring mode may be a mode for monitoring one of the first electric path and the second electric path while at least one of the first power conversion device and the second power conversion device is not in operation.

In an embodiment of the insulation monitoring method, the connecting step may be to connect to the first channel unit when the monitoring mode is a mode for monitoring the first electric path, and to connect to the second channel unit when the monitoring mode is a mode for monitoring the second electric path.

In an embodiment of the insulation monitoring method, the determining step may be to calculate magnitude of insulation resistance of an electric path connected to the connected channel unit based on the measurement signal, and determine an insulation status of the electric path connected to the connected channel unit based on the magnitude of the insulation resistance.

The embodiments of the insulation monitoring device, insulation monitoring system, and insulation monitoring method described above are not limited to those described above, and may include embodiments described in the specific description to be described below or embodiments that can be inferred/derived from the specific description.

According to the embodiments of the insulation monitoring device, insulation monitoring system, and insulation monitoring method described above, an IMD on an AC side of one system monitors insulation on a DC side of another system by utilizing a coupler arranged on the AC side of the another system, thereby enabling an IMD arranged on the AC side of the another system to be replaced with the IMD on the AC side of the one system.

Accordingly, the IMD arranged on the another system can be excluded, which has the effect of enabling insulation monitoring on the AC sides of the plurality of systems while reducing the number of IMDs arranged in the systems.

By reducing the number of IMDs installed in the system, installation costs and inconveniences can be reduced, and an installation space can be secured.

By reducing the number of IMDs installed in the plurality of systems, an insulation monitoring system for monitoring insulation of the plurality of systems can be established more conveniently and easily.

The embodiments of the insulation monitoring device, insulation monitoring system, and insulation monitoring method described above are not limited to those described above, and may include embodiments described in the specific description to be described below or effects that can be inferred/derived from the specific description.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a typical insulation monitoring device (IMD);

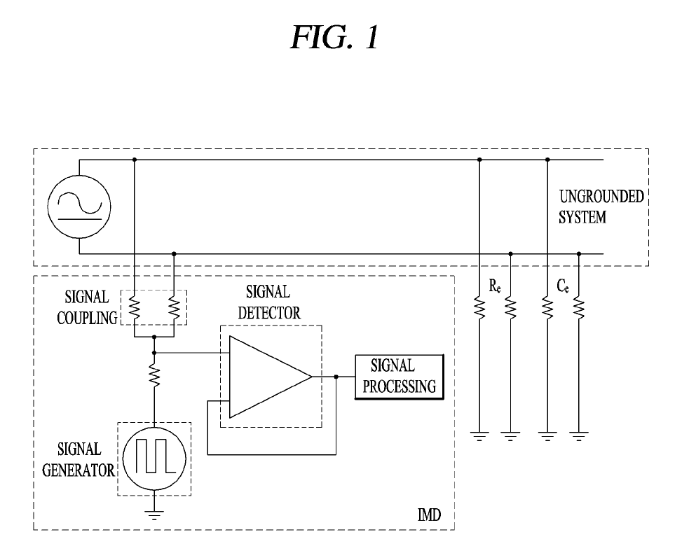

FIG. 2 is a schematic diagram 1 for insulation monitoring of a system including the related art power conversion device and a load;

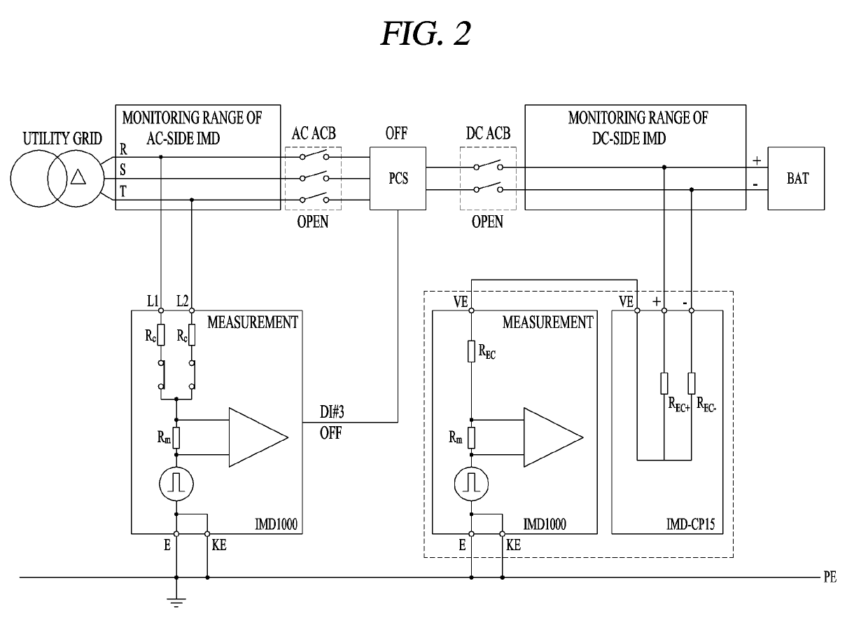

FIG. 3 is a schematic diagram 2 for insulation monitoring of a system including the related art power conversion device and a load;

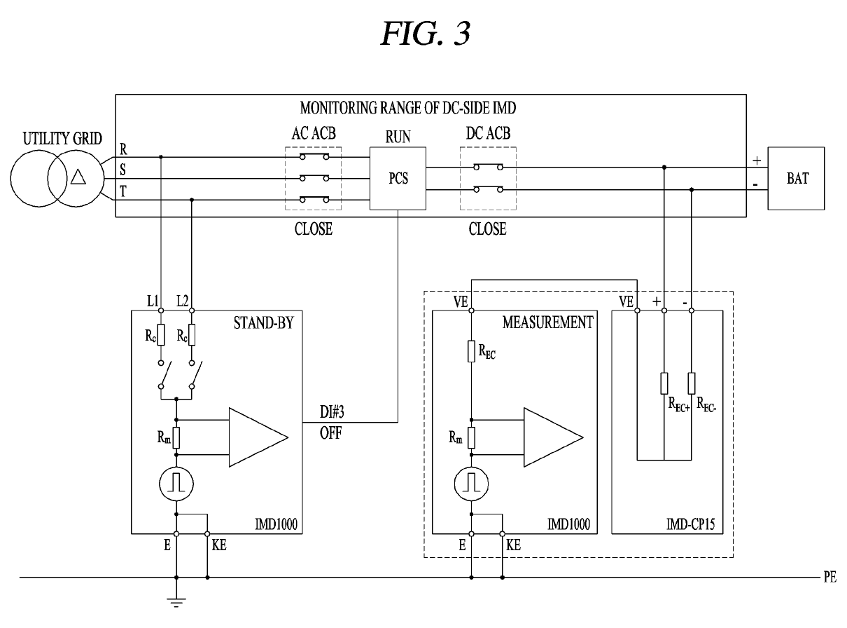

FIG. 4 is a configuration diagram for monitoring insulation of a plurality of systems connected to the related art multi-winding transformer;

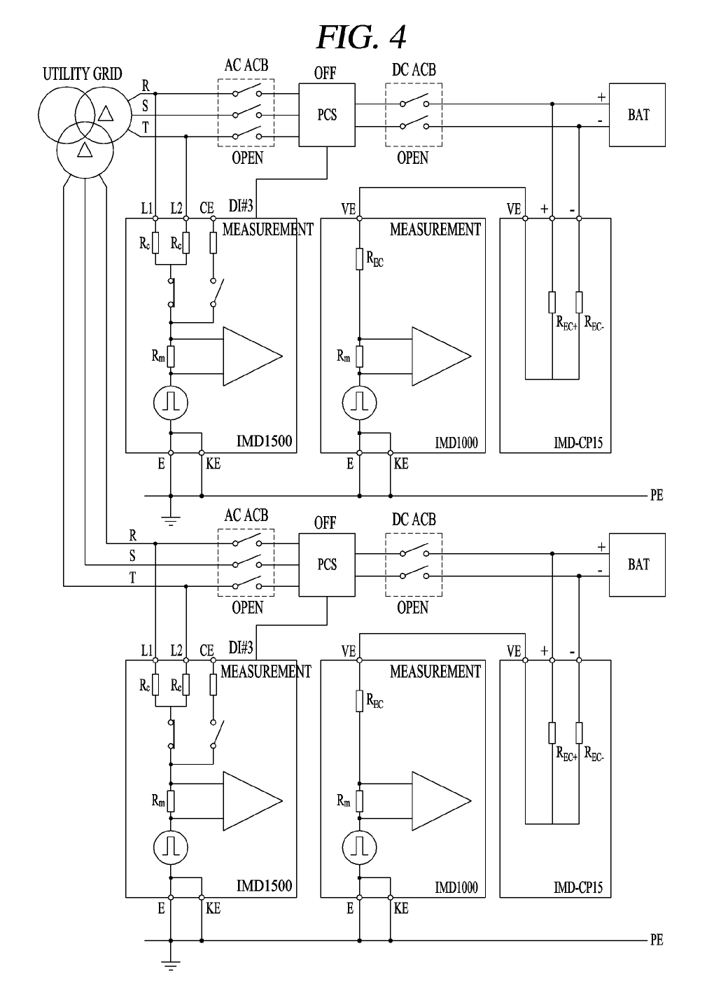

FIG. 5 is a schematic diagram of an insulation monitoring device (IMD) and an insulation monitoring system according to an embodiment;

FIG. 6 is an exemplary diagram 1 showing a specific operation example of an IMD and an insulation monitoring system according to an embodiment;

FIG. 7 is an exemplary diagram 2 showing a specific operation example of an IMD and an insulation monitoring system according to an embodiment;

FIG. 8 is an exemplary diagram 3 showing a specific operation example of an IMD and an insulation monitoring system according to an embodiment; and

FIG. 9 is a flowchart of an insulation monitoring method according to an embodiment.

### DETAILED DESCRIPTION

Hereinafter, embodiments of an insulation monitoring device (IMD), an insulation monitoring system, and an insulation monitoring method will be described in detail with reference to the attached drawings. However, when it is determined that a specific description of a related known technology may obscure the gist of the embodiments in describing the embodiments, the detailed descriptions thereof will be omitted, and among the omitted descriptions, the basic configuration of the insulation monitoring device, the operating principle, the configuration of a grid system, and the operating principle and each configuration of the grid system may refer to the above-mentioned prior art document.

The accompanying drawings are used to help easily understand embodiments of the disclosure and it should be understood that the idea of the disclosure is not limited by the accompanying drawings. The idea of the disclosure should be construed to extend to any alterations, equivalents, and substitutes besides the accompanying drawings.

### Insulation monitoring device IMD

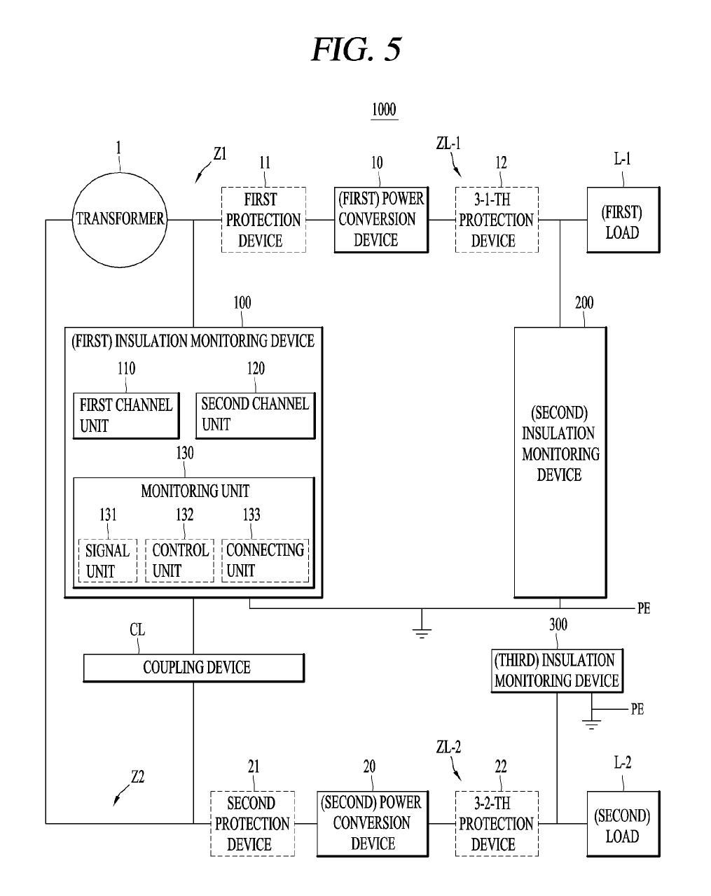

An insulation monitoring device (IMD) 100 according to an embodiment may be a device that monitors insulation of a (power) system 1000 as shown in FIG. 5.

The insulation monitoring device 100 monitors the insulation of a plurality of systems, which are connected to a multi-winding transformer 1 (hereinafter, referred to as a transformer) in the system 1000.

The system 1000 is a system to which a plurality of power grids are connected, and may be a power grid in which the transformer 1 transforms AC power supplied from a power supply network and supplies the transformed power to power conversion devices 10 and 20, and the power conversion devices 10 and 20 convert the received power and supply the converted power to corresponding loads L-1 and L-2.

The transformer 1, the power conversion devices 10 and 20, and the loads L-1 and L-2 may each be connected via a plurality of electric paths, so that power can flow.

In this way, the system 1000 in which the transformer 1, the power conversion devices 10 and 20, and the loads L-1 and L-2 are connected may be a non-grounded system with no ground connection.

The transformer 1 may be connected to each of the plurality of power grids to supply power to the plurality of power grids.

Here, the plurality of power grids may include the power conversion devices 10 and 20, respectively.

Accordingly, the plurality of power grids may be divided based on whether or not the power conversion devices 10 and 20 are included.

The plurality of power grids connected to the transformer 1 may be at least three power grids.

In the following, for the convenience of explanation, the embodiments will be described focusing on an example in which two power grids, a first system and a second system, are connected to the transformer 1. However, it is assumed that the specific implementation/application/utilization of the embodiments may also be carried out in cases where there are at least three power grids.

The transformer 1 may transform a voltage of AC power and transmit the transformed voltage to the power conversion devices 10 and 20 arranged in the plurality of power grids, respectively.

The power conversion devices 10 and 20 may be power conditioning systems (PCSs).

The power conversion devices 10 and 20 may convert AC power into DC power.

Accordingly, each of the power conversion devices 10 and 20 arranged in each of the plurality of power grids can convert AC power supplied from the transformer 1 into DC power and supply the converted DC power to each of the loads L-1 and L-2.

That is, AC power can flow in electric paths Z1 and Z2 between the transformer 1 and the power conversion devices 10 and 20 and DC power can flow in electric paths ZL-1 and ZL-2 between the power conversion devices 10 and 20 and the loads ZL-1 and ZL-2.

As such, the system 1000 can be divided into a first zone Z1 between the transformer 1 and the first power conversion device 10 through which AC power flows, a second zone Z2 between the transformer 1 and the second power conversion device 20, a 3-1-th zone ZL-1 between the first power conversion device 10 and the first load L-1 through which DC power flows, and a 3-2-th zone ZL-2 between the second power conversion device 20 and the second load L-2.

Among the zones Z1, Z2, ZL-1, and ZL-2 of the system 1000, insulation monitoring devices 100, 200, and 300 may be installed in the first zone Z1, the 3-1-th zone ZL-1, and the 3-2-th zone ZL-2, respectively, to perform insulation monitoring.

The insulation monitoring device 100 according to the embodiment is a device that monitors insulation occurring in an electric path of the first zone Z1 among the plurality of zones of the system 1000, and may be configured as a separate device from a coupling device CL installed in the second zone Z2, the second insulation monitoring device 200, and the third insulation device 300.

The insulation monitoring device 100 includes a first channel unit 110, a second channel unit 120, and a monitoring unit 130.

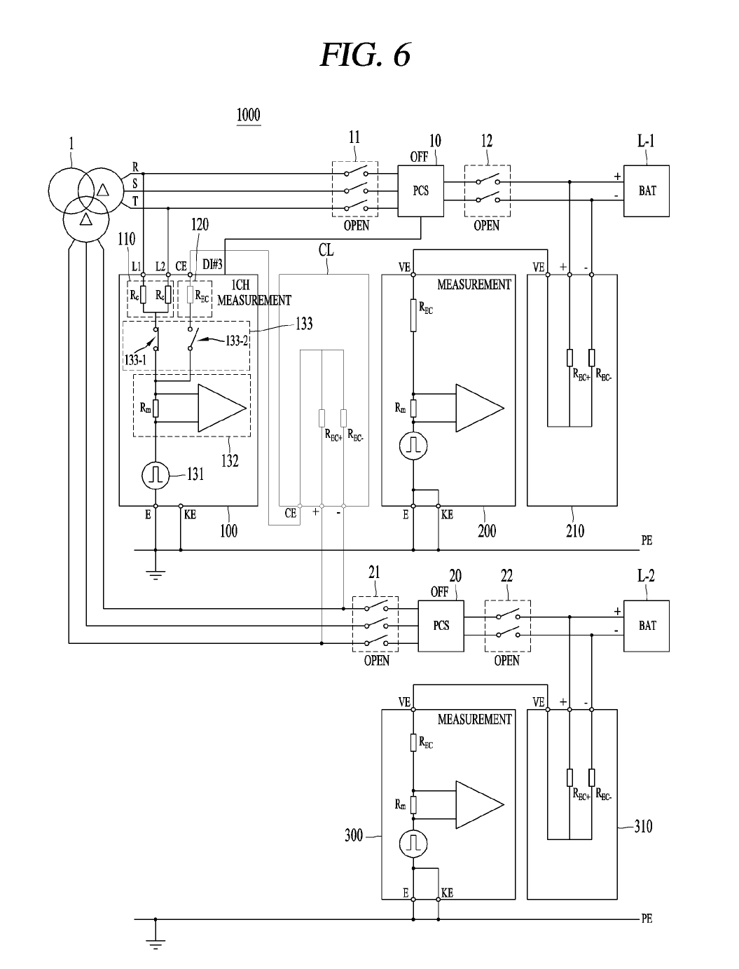

In this way, the specific configuration of the insulation monitoring device 100 including the first channel unit 110, the second channel unit 120, and the monitoring unit 130 may be as shown in FIGS. 6 to 8.

In the insulation monitoring device 100, the first channel unit 110 is connected to an electric path of the first zone Z1 between the transformer 1 and the first power conversion device 10 of the first system.

The first channel unit 110 may include a plurality of terminals L1 and L2 through which signals are input and output in the insulation monitoring device 100.

The first channel unit 110 may also include a plurality of resistors Re on paths through which signals are input and output.

The first channel unit 110 may be connected to at least two electric paths R and T among electric paths of the first zone Z1 through the plurality of terminals L1 and L2, to receive signals from the electric paths of the first zone Z1 or output signals to the electric paths of the first zone Z1.

When the first channel unit 110 receives a signal from the electric path of the first zone Z1, the first channel unit 110 may transmit the received signal to the monitoring unit 130.

When receiving a signal from the monitoring unit 130, the first channel unit 110 may also output the received signal to the electric path of the first zone Z1.

In the insulation monitoring device 100, the second channel unit 120 is connected to a coupling device CL, which is connected to the electric path of the second zone Z2 between the transformer 1 and the second power conversion device 20 of a second system.

The second channel unit 120 may include a coupling terminal CE through which signals are input and output in the insulation monitoring device 100.

The second channel unit 120 may also include a resistor Re in a path through which a signal is input and output.

The second channel unit 120 may be connected to the coupling device CL through the coupling terminal CE, to receive a signal from the coupling device CL or output a signal to the coupling device CL.

The coupling device CL may be connected to the electric paths R and T of the second zone Z2, to receive signals from the electric paths of the second zone Z2 or output signals to the electric paths of the second zone Z2.

The coupling device CL may include resistors Rec+ and Rec- in paths through which signals are input and output.

Upon receiving a signal from the electric path of the second zone Z2, the coupling device CL may transmit the received signal to the second channel unit 120, and upon receiving a signal from the second channel unit 120, the coupling device CL may output the received signal to the electric path of the second zone Z2.

When the second channel unit 120 receives a signal from the coupling device CL, the second channel unit 110 may transmit the received signal to the monitoring unit 130.

When receiving a signal from the monitoring unit 130, the second channel unit 120 may also output the received signal to the coupling device CL.

In the insulation monitoring device 100, the monitoring unit 130 is connected to a ground PE that is not connected to the electric path of the first system 1, and is connected to one of the first channel unit 110 and the second channel unit 120 according to an operation signal received from at least one of the first power conversion device 10 and the second power conversion device 20, to apply a predetermined signal to one of the ground PE and the connected channel unit, receive a measurement signal corresponding to the predetermined signal from the other, and determines an insulation status of a zone corresponding to the connected channel unit based on the measurement signal.

That is, the monitoring unit 130 may be connected to one of the first channel unit 110 and the second channel unit 120 while connected to the ground PE. Accordingly, the monitoring unit 130 may apply the predetermined signal to one of the ground PE and the connected channel unit, receive the measuring signal from the other, and determine the insulation status of one of the first zone Z1 and the second zone Z2 based on the measuring signal.

For example, when applying the predetermined signal to the ground PE while the monitoring unit 130 is connected to the first channel unit 110, the predetermined signal may be applied to the monitoring unit 130 in the form of the measurement signal sequentially via the ground PE, a virtual electric path between the ground PE and the first system, the electric path of the first zone Z1, and the first channel unit 110, such that the monitoring unit 130 can determine the insulation status of the first zone Z1 based on the measurement signal.

On the other hand, when applying the predetermined signal to the first channel unit 110 while the monitoring unit 130 is connected to the first channel unit 110, the predetermined signal may be applied to the monitoring unit 130 in the form of the measurement signal sequentially via the first channel unit 110, the electric path of the first zone Z1, the virtual electric path between the ground PE and the first system, and the ground PE, such that the monitoring unit 130 can determine the insulation status of the first zone Z1 based on the measurement signal.

In another example, when applying the predetermined signal to the ground PE while the monitoring unit 130 is connected to the second channel unit 120, the predetermined signal may be applied to the monitoring unit 130 in the form of the measurement signal sequentially via the ground PE, the virtual electric path between the ground PE and the second system, the electric path of the second zone Z2, the coupling device CL, and the second channel unit 120, such that the monitoring unit 130 can determine the insulation status of the second zone Z2 based on the measurement signal.

On the other hand, when applying the predetermined signal to the second channel unit 120 while the monitoring unit 130 is connected to the second channel unit 120, the predetermined signal may be applied to the monitoring unit 130 in the form of the measurement signal sequentially via the second channel unit 120, the coupling device CL, the electric path of the second zone Z2, the virtual electric path between the ground PE and the second system, and the ground PE, such that the monitoring unit 130 can determine the insulation status of the second zone Z2 based on the measurement signal.

That is, the insulation monitoring device 100 can selectively determine the insulation status of any one of the first zone Z1 and the second zone Z2 by the configuration in which the first channel unit 110 is connected to the electric path of the first zone Z1, the second channel unit 120 is connected to the coupling device CL connected to the electric path of the second zone Z2, and the monitoring unit 130 is connected to one of the first channel unit 110 or the second channel unit 120.

Accordingly, insulation monitoring of two zones, namely, the first zone Z1 and the second zone Z2, can be performed using one insulation monitoring device 100.

The monitoring unit 130 may include a signal unit 131 that applies the predetermined signal to the ground PE or the connected channel unit, a control unit 132 that receives the measurement signal from the ground PE or the connected channel unit and determines the insulation status of a zone corresponding to the connected channel unit based on the measurement signal, and a connecting unit 133 that connects or disconnects one of the first channel unit 110 and the second channel unit 120 to or from the control unit 132.

The signal unit 131 may include a signal generator.

The signal unit 131 may be controlled by the control unit 132.

The signal unit 131 may generate the predetermined signal and apply the predetermined signal to the ground PE or the connected channel unit.

The control unit 132 may include a computing device.

The control unit 132 may control each of the signal unit 131 and the connecting unit 133.

The control unit 132 may be connected to one of the first channel unit 110 and the second channel unit 120 by the connecting unit 133, and may determine the insulation status of the zone corresponding to the connected channel unit based on the measurement signal received from the ground PE or the connected channel unit.

The connecting unit 133 may include a switching device.

The connecting unit 133 may be controlled by the control unit 132.

The connecting unit 133 may include a first switching portion 133-1 that is arranged between the first channel unit 110 and the control unit 132 to connect or disconnect the first channel unit 110 to or from the control unit 132 according to a switching operation, and a second switching portion 133-2 that is arranged between the second channel unit 120 and the control unit 132 to connect or disconnect the second channel unit 120 to or from the control unit 132 according to a switching operation.

Here, the connection may mean that two objects are electrically connected, and the disconnection may mean that two objects are electrically disconnected. In the following description, connection and disconnection are used as such meaning.

Each of the first switching portion 133-1 and the second switching portion 133-2 may connect two objects on opposite sides during a closing operation, while disconnecting the two objects on the opposite sides during an opening operation.

In this case, one of the first switching portion 133-1 and the second switching portion 133-2 may be open when the other is closed.

That is, one of the first switching portion 133-1 and the second switching portion 133-2 of the connecting unit 133 may be closed.

Accordingly, the monitoring unit 130 can be connected to one of the first channel unit 110 and the second channel unit 120.

The monitoring unit 130 may selectively determine the insulation status of any one of the first zone Z1 and the second zone Z2 in a manner that the signal unit 131 applies the predetermined signal to one of the ground PE and the connected channel unit, the control unit 132 receives the measurement signal from the other of the ground PE and the connected channel unit, to which the predetermined signal has not been applied, and determines the insulation status of a zone corresponding to the connected channel unit based on the measurement signal, and the connecting unit 133 connects or disconnects the control unit 132 to or from one of the first channel unit 110 and the second channel unit 120.

For convenience of explanation, the following description will be given under assumption that the monitoring unit 130 includes the signal unit 131, the control unit 132, and the connecting unit 133.

Meanwhile, the system 1000 may include a first protection device 11 that connects or disconnects the transformer 1 to or from the first power conversion device 10 in the first zone Z1.

The first protection device 11 may be an AC-only protection device.

The first protection device 11 may be a protection device that connects or disconnects two objects by closing or opening contacts connected to electric paths of the two objects on the opposite sides.

The first protection device 11 may connect the electric path between the two objects during closing operation, and disconnect the electric path between the two objects during opening operation.

The first protection device 11 may be, for example, an air circuit breaker (ACB).

The first protection device 11 may perform a closing operation or an opening operation based on a signal received from the first power conversion device 10, a control device controlling the first power conversion device 10, or an operating device of the system 1000.

When the first protection device 11 is arranged between the transformer 1 and the first power conversion device 10, the first channel unit 110 may be connected to the electric path between the transformer 1 and the first protection device 11.

That is, the insulation monitoring device 100 can monitor the insulation of the electric path between the transformer 1 and the first protection device 11 among electric paths in the first zone Z1.

One of the first channel unit 110 and the second channel unit 120 may be connected to the monitoring unit 130 when the first protection device 11 is open.

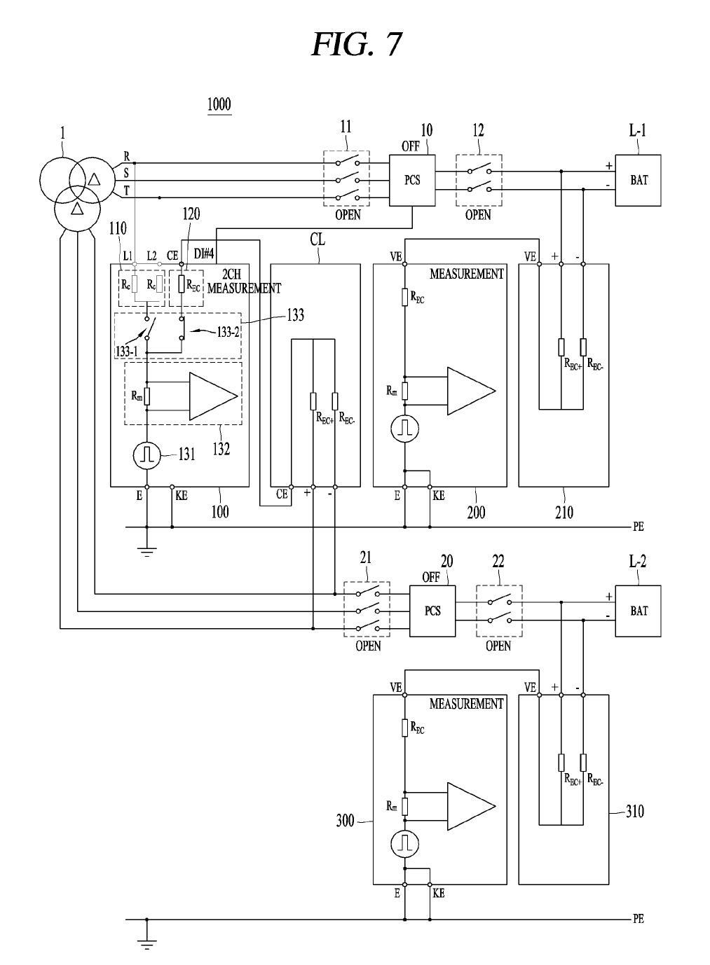

That is, as shown in FIGS. 6 and 7, one of the first channel unit 110 and the second channel unit 120 may be connected to the monitoring unit 130 while the transformer 1 and the first power conversion device 10 are disconnected.

Accordingly, when the first protection device 11 is open and the transformer 1 and the first power conversion device 10 are disconnected, any one of the first channel unit 110 and the second channel unit 120 can be connected to the monitoring unit 130, enabling the insulation monitoring device 100 to monitor the insulation of one of the first zone Z1 and the second zone Z2.

The first channel unit 110 and the second channel unit 120 may not be connected to the monitoring unit 130 when the first protection device 11 is closed.

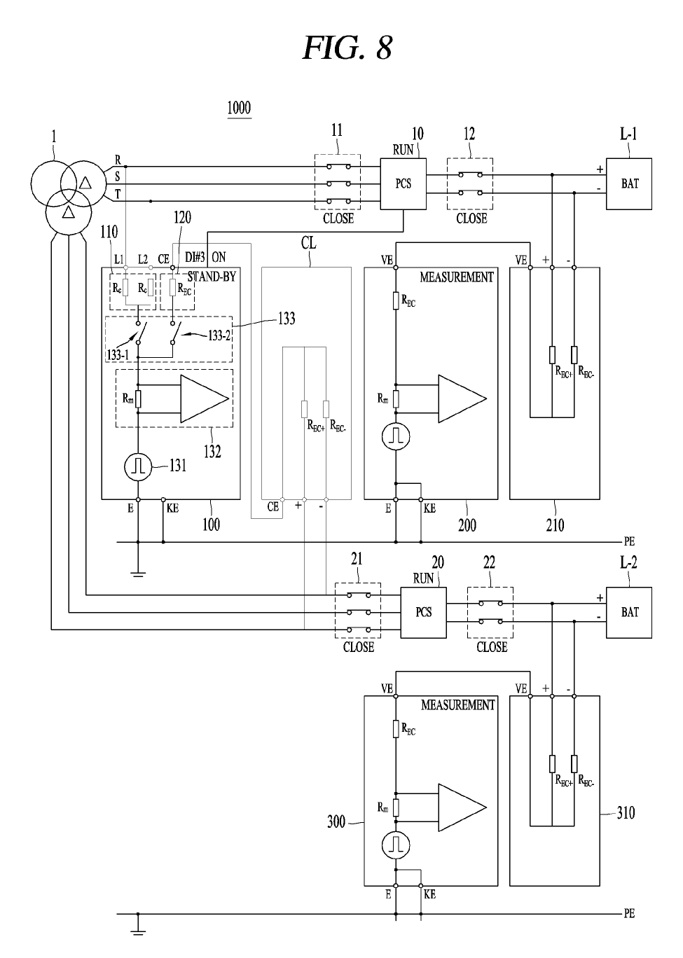

That is, as shown in FIG. 8, the first channel unit 110 and the second channel unit 120 may not be connected to the monitoring unit 130 while the transformer 1 and the first power conversion device 10 are connected.

Accordingly, when the first protection device 11 is closed and the transformer 1 and the first power conversion device 10 are connected, the first channel unit 110 and the second channel unit 120 may not be connected to the monitoring unit 130, suppressing the insulation monitoring device 100 from monitoring the insulation of the first zone Z1 and the second zone Z2.

Meanwhile, the system 1000 may include a second protection device 21 that connects or disconnects the transformer 1 to or from the second power conversion device 20 in the second zone Z2.

The second protection device 21 may be an AC-only protection device.

The second protection device 21 may be a protection device that connects or disconnects two objects by closing or opening contacts connected to an electric path between the two objects on opposite sides.

The second protection device 21 may connect the electric path between the two objects during closing operation, and disconnect the electric path between the two objects during opening operation.

The second protection device 21 may be, for example, an air circuit breaker (ACB).

The second protection device 21 may perform a closing operation or an opening operation based on a signal received from the second power conversion device 20, a control device controlling the second power conversion device 20, or an operating device of the system 1000.

When the second protection device 21 is arranged between the transformer 1 and the second power conversion device 20, the second channel unit 120 may be connected to the electric path between the transformer 1 and the second protection device 21.

That is, the coupling device CL may be connected to the electric path between the transformer 1 and the second protection device 21, and the second channel unit 120 may be connected to the coupling device CL so as to be connected to the electric path between the transformer 1 and the second protection device 21 through the coupling device CL.

Accordingly, the insulation monitoring device 100 can monitor the insulation of the electric path between the transformer 1 and the second protection device 21 among the electric paths in the second zone Z2.

One of the first channel unit 110 and the second channel unit 120 may be connected to the monitoring unit 130 when the second protection device 21 is open.

That is, as shown in FIGS. 6 and 7, one of the first channel unit 110 and the second channel unit 120 may be connected to the monitoring unit 130 while the transformer 1 and the second power conversion device 20 are disconnected.

Accordingly, when the second protection device 21 is open and the transformer 1 and the second power conversion device 20 are disconnected, any one of the first channel unit 110 and the second channel unit 120 can be connected to the monitoring unit 130, enabling the insulation monitoring device 100 to monitor the insulation of one of the first zone Z1 and the second zone Z2.

The first channel unit 110 and the second channel unit 120 may not be connected to the monitoring unit 130 when the second protection device 21 is closed.

That is, as shown in FIG. 8, the first channel unit 110 and the second channel unit 120 may not be connected to the monitoring unit 130 while the transformer 1 and the second power conversion device 20 are connected.

Accordingly, when the second protection device 21 is closed and the transformer 1 and the second power conversion device 20 are connected, the first channel unit 110 and the second channel unit 120 may not be connected to the monitoring unit 130, suppressing the insulation monitoring device 100 from monitoring the insulation of the first zone Z1 and the second zone Z2.

In this way, one of the first channel unit 110 and the second channel unit 120 can be connected to the monitoring unit 130 when the first protection device 11 and the second protection device 21 are open, and can be disconnected from the monitoring unit 130 when the first protection device 11 and the second protection device 21 are closed.

When the first protection device 11 and the second protection device 21 are open and one of the first channel unit 110 and the second channel unit 120 is connected to the monitoring unit 130, as shown in FIGS. 6 and 7, the monitoring unit 130 can monitor the insulation of the zone corresponding to the connected channel unit, and when the first protection device 11 and the second protection device 21 are closed and the first channel unit 110 and the second channel unit 120 are not connected to the monitoring unit 130, as shown in FIG. 8, a second insulation monitoring device 200 connected to the electric path between the first power conversion device 10 and the first load L-1 can monitor the insulation of the first system and a third insulation monitoring device 300 connected to the electric path between the second power conversion device 20 and the second load L-2 can monitor the insulation of the second system.

In the insulation monitoring device 100 as described above, the monitoring unit 130 can be connected to one of the first channel unit 110 and the second channel unit 120 according to a signal received from the first power conversion device 10, the second power conversion device 20, a control device controlling the first power conversion device 10, a control device controlling the second power conversion device 20, or an operating device of the system 1000, thereby determining the insulation status of one of the first zone Z1 and the second zone Z2.

Hereinafter, for convenience of explanation, the description will focus on an example in which the monitoring unit 130 operates based on a signal received from at least one of the first power conversion device 10 and the second power conversion device 20. However, the operation of the monitoring unit 130 may also be performed based on a signal received from a control device controlling the first power conversion device 10, a control device controlling the second power conversion device 20, or an operating device of the system 1000.

The monitoring unit 130 may monitor the insulation of one of the first zone Z1 and the second zone Z2 by determining the insulation status of the one of the first zone Z1 and the second zone Z2.

When receiving a first operation signal from at least one of the first power conversion device 10 and the second power conversion device 20, the monitoring unit 130 may be connected to the first channel unit 110 and determine the insulation status of the first zone Z1 based on the measurement signal received from the ground PE or the first channel unit 110.

That is, when receiving the first operation signal, the monitoring unit 130 may be connected to the first channel unit 110 and disconnected from the second channel unit 120, as shown in FIG. 6, and may monitor the insulation of the first zone Z1 by determining the insulation status of the first zone Z1 based on the measurement signal received from the ground PE or the first channel unit 110.

In this case, the monitoring unit 130 may receive the measurement signal from the first channel unit 110 when applying the predetermined signal to the ground PE, and may receive the measurement signal from the ground PE when applying the predetermined signal to the first channel unit 110.

Here, the first operation signal may be transmitted to the monitoring unit 130 while the first protection device 11 and the second protection device 21 are open.

The first operation signal may also be transmitted to the monitoring unit 130 when monitoring the insulation of the first zone Z1.

When receiving a second operation signal from at least one of the first power conversion device 10 and the second power conversion device 20, the monitoring unit 130 may be connected to the second channel unit 120 and determine the insulation status of the second zone Z2 based on the measurement signal received from the ground PE or the second channel unit 120.

That is, when receiving the second operation signal, the monitoring unit 130 may be connected to the second channel unit 120 and disconnected from the first channel unit 110, as shown in FIG. 7, and may monitor the insulation of the second zone Z2 by determining the insulation status of the second zone Z2 based on the measurement signal received from the ground PE or the second channel unit 120.

In this case, the monitoring unit 130 may receive the measurement signal from the second channel unit 120 when applying the predetermined signal to the ground PE, and may receive the measurement signal from the ground PE when applying the predetermined signal to the second channel unit 120.

Here, the second operation signal may be transmitted to the monitoring unit 130 while the first protection device 11 and the second protection device 21 are open.

The second operation signal may also be transmitted to the monitoring unit 130 when monitoring the insulation of the second zone Z2.

In this way, the monitoring unit 130 that is connected to one of the first channel unit 110 and the second channel unit 120 and receives the measurement signal to determine the insulation status of one of the first zone Z1 and the second zone Z2 can calculate the magnitude of insulation resistance in a zone corresponding to the connected channel unit based on the measurement signal and determine the insulation status of the zone corresponding to the connected channel unit based on the magnitude of the insulation resistance.

For example, the magnitude of the insulation resistance may be compared with a predetermined reference value. When the magnitude of the insulation resistance is greater than or equal to the predetermined reference value as a result of the comparison, the insulation status of the zone corresponding to the connected channel unit may be determined to be abnormal. On the other hand, when the magnitude of the insulation resistance is smaller than the predetermined reference value, the insulation status of the zone corresponding to the connected channel unit may be determined to be normal.

Here, the magnitude of the insulation resistance may be calculated based on a voltage of the measurement signal, a voltage of the predetermined signal, and a magnitude of internal resistance of an electric path through which the predetermined signal passes, and the predetermined reference value may include a plurality of reference values corresponding to a plurality of resistance values, respectively.

When receiving a third operation signal from the first power conversion device 10, the monitoring unit 130 may not be connected to the first channel unit 110 and the second channel unit 120, and thus may not determine the insulation status of the first zone Z1 and the second zone Z2.

That is, when receiving the third operation signal, as shown in FIG. 8, the monitoring unit 130 may be disconnected from the first channel unit 110 and the second channel unit 120, and thus may not monitor the insulation of the first zone Z1 and the second zone Z2.

In this case, the second insulation monitoring device 200 may monitor the insulation of the first zone Z1 by determining the insulation status of the entire zone of the first system including the first zone Z1 in the 3-1-th zone ZL-1, and the third insulation monitoring device 300 may monitor the insulation of the second zone Z2 by determining the insulation status of the entire zone of the second system including the second zone Z2 in the 3-2-th zone ZL-2.

Here, the third operation signal may be transmitted to the monitoring unit 130 while the first protection device 11 and the second protection device 21 are closed.

Here, the third operation signal may be transmitted to the monitoring unit 130 when the first power conversion device 10 and the second power conversion device 20 perform power conversion operation.

The insulation monitoring device 100 described above may be applied to an insulation monitoring system 1000 and an insulation monitoring method according to embodiments to be described below, or may be implemented by applying the embodiments to be described below, and may also be implemented independently of the embodiments to be described below.

### Insulation Monitoring System

Hereinafter, an insulation monitoring system according to an embodiment will be described, but any part that overlaps the contents of the insulation monitoring device 100 described above will be omitted on the premise that the description of the insulation monitoring device 100 is equally applicable.

The insulation monitoring system 1000 according to the embodiment may be a system that monitors insulation in the (power) system 1000 as shown in FIG. 5.

The insulation monitoring system 1000 includes the transformer 1 that transmits three-phase AC voltage, the first power conversion device 10 that is installed in a first system and receives the AC voltage from the transformer 1 and converts the AC voltage into a DC voltage, the second power conversion device 20 that is installed in a second system and receives the AC voltage from the transformer 1 and converts the AC voltage into a DC voltage, the first insulation monitoring device 100 that monitors the insulation of a first electric path Z1 which is a primary side of the first power conversion device 10, the coupling device CL that receives a signal from a second electric path Z2 which is a primary side of the second power conversion device 20, the second insulation monitoring device 200 that monitors the insulation of a first load-side electric path ZL-1, which receives the DC voltage from the first power conversion device 10, and the third insulation monitoring device 300 that monitors the insulation of a second load-side electric path ZL-2, which receives the DC voltage from the second power conversion device 20.

That is, the insulation monitoring system 1000 may be configured such that the insulation of the first electric path Z1 and the second electric path Z2 can be monitored by the first insulation monitoring device 100, the insulation of the first load-side electric path ZL-1 can be monitored by the second insulation monitoring device 200, and the insulation of the second load-side electric path ZL-2 can be monitored by the third insulation monitoring device 300.

In the insulation monitoring system 1000, the first insulation monitoring device 100 includes the first channel unit 110 that receives a signal from the first electric path Z1, the second channel unit 120 that receives a signal, which is received from the second electric path Z2, from the coupling device CL, the signal unit 131 that applies a predetermined signal to the ground PE, which is not connected to the first system and the second system, the control unit 132 that is connected to one of the first channel unit 110 and the second channel unit 120 to receive the measurement signal corresponding to the predetermined signal from the connected channel unit and determine the insulation status of an electric path corresponding to the connected channel unit based on the measurement signal, and the connecting unit 133 that connects the first channel unit 110 to the control unit 132 upon monitoring the first electric path Z1 and connects the second channel unit 120 to the control unit 132 upon monitoring the second electric path Z2.

That is, the first insulation monitoring device 100 may include the first channel unit 110, the second channel unit 120, the signal unit 131, the control unit 132, and the connecting unit 133, to monitor insulation by determining the insulation status of any one electric path of the first electric path Z1 and the second electric path Z2.

The insulation monitoring system 1000 may further include the first protection device 11 that connects or disconnects the transformer 1 to or from the first power conversion device 10 in the first electric path Z1, and the second protection device 21 that connects or disconnects the transformer 1 to or from the second power conversion device 20 in the second electric path Z2.

In this case, the first insulation monitoring device 100 may be connected to an electric path between the transformer 1 and the first protection device 11, and the coupling device CL may be connected to an electric path between the transformer 1 and the second protection device 21.

The insulation monitoring system 1000 may further include a 3-1-th protection device 12 that connects or disconnects the first power conversion device 10 to or from the first load L-1 in a secondary-side electric path of the first power conversion device 10, and a 3-2-th protection device 22 that connects or disconnects the second power conversion device 20 to or from the second load L-2 in a secondary-side electric path of the second power conversion device 20.

In this case, the second insulation monitoring device 200 may be connected to an electric path between the 3-1-th protection device 12 and the first load L-1, and the third insulation monitoring device 300 may be connected to an electric path between the 3-2-th protection device 22 and the second load L-2.

The connecting unit 133, as shown in FIGS. 6 and 7, may connect the control unit 132 to one of the first channel unit 110 and the second channel unit 120 when the first protection device 11 disconnects the transformer 1 from the first power conversion device 10 and the second protection device 21 disconnects the transformer 1 from the second power conversion device 20.

As the control unit 132 is connected to one of the first channel unit 110 and the second channel unit 120 while the first protection device 11 and the second protection device 21 are open, the first insulation monitoring device 100 can determine the insulation status of one of the electric path between the transformer 1 and the first protection device 11 in the first electric path Z1 and the electric path between the transformer 1 and the second power conversion device 20 in the second electric path Z2.

In this case, the second insulation monitoring device 200 may determine the insulation status of an electric path between the 3-1-th protection device 12 and the first load L-1 in the first load-side electric path ZL-1, and the third insulation monitoring device 300 may determine the insulation status of an electric path between the 3-2-th protection device 22 and the second load L-2 in the second load-side electric path ZL-2.

When the first protection device 11 and the second protection device 21 are open and the control unit 132 is connected to one of the first channel unit 110 and the second channel unit 120, the 3-1-th protection device 12 may disconnect the first power conversion device 10 from the first load L-1 and the 3-2-th protection device 22 may disconnect the second power conversion device 20 from the second load L-2.

The connecting unit 133, as shown in FIGS. 8, may disconnect the first channel unit 110 and the second channel unit 120 from the control unit 132 when the first protection device 11 connects the transformer 1 to the first power conversion device 10 and the second protection device 21 connects the transformer 1 to the second power conversion device 20.

As the control unit 132 is disconnected from the first channel unit 110 and the second channel unit 120 while the first protection device 11 and the second protection device 21 are closed, the first insulation monitoring device 100 can determine the insulation status of the electric path between the transformer 1 and the first protection device 11 in the first electric path Z1 and the electric path between the transformer 1 and the second power conversion device 20 in the second electric path Z2.

In this case, the second insulation monitoring device 200 may determine the insulation status of the first system which includes the first electric path Z1 and the first load-side electric path ZL-1, and the third insulation monitoring device 300 may determine the insulation status of the second system including the second electric path Z2 and the second load-side electric path ZL-2.

The connecting unit 133 may include the first switching portion 133-1 and the second switching portion 133-2, as shown in FIGS. 6 to 8.

The first switching portion 133-1 may connect the first channel unit 110 to the control unit 132 when monitoring the first electric path Z1, and may disconnect the first channel unit 110 from the control unit 132 when monitoring the second electric path Z2.

Here, when monitoring the first electric path Z1, the first protection device 11 and the second protection device 21 may be in an open state.

When monitoring the first electric path Z1, at least one of the 3-1-th protection device 12 and the 3-2-th protection device 22 may also be in an open state.

The first switching portion 133-1 may also disconnect the first channel unit 110 from the control unit 132 when the first protection device 11 and the second protection device 21 are closed.

The second switching portion 133-2 may connect the second channel unit 120 to the control unit 132 when monitoring the second electric path Z2, and may disconnect the second channel unit 120 from the control unit 132 when monitoring the first electric path Z1.

Here, when monitoring the second electric path Z2, the first protection device 11 and the second protection device 21 may be in an open state.

When monitoring the second electric path Z2, at least one of the 3-1-th protection device 12 and the 3-2-th protection device 22 may also be in an open state.

The second switching portion 133-2 may also disconnect the second channel unit 120 from the control unit 132 when the first protection device 11 and the second protection device 21 are closed.

In this case, at least one of the 3-1-th protection device 12 and the 3-2-th protection device 22 may also be in a closed state.

As such, in the first insulation monitoring device 100, the first switching portion 133-1 may connect the first channel unit 110 to the control unit 132 and the second switching portion 133-2 may disconnect the second channel unit 120 from the control unit 132, as shown in FIG. 6, when monitoring the first electric path Z1, the first switching portion 133-1 may disconnect the first channel unit 110 from the control unit 132 and the second switching portion 133-2 may connect the second channel unit 120 to the control unit 132, as shown in FIG. 7, when monitoring the second electric path Z2, and the first switching portion 133-1 may disconnect the first channel unit 110 from the control unit 132 and the second switching portion 133-2 may disconnect the second channel unit 120 from the control unit 132, as shown in FIG. 8, when the first protection device 11 and the second protection device 21 are closed.

In case of monitoring the first electric path Z1, as shown in FIG. 6, the first switching portion 133-1 may connect the first channel unit 110 to the control unit 132 and the signal unit 131 may apply the predetermined signal to the ground PE, such that the first channel unit 110 may receive the measurement signal from the first electric path Z1 and the control unit 132 may receive the measurement signal from the first channel unit 110. Accordingly, the first insulation monitoring device 100 can determine the insulation status of the first electric path Z1 based on the measurement signal.

That is, when monitoring the first electric path Z1, as shown in FIG. 6, the control unit 132 may be connected to the first channel unit 110 and disconnected from the second channel unit 120, to monitor the insulation of the first electric path Z1 by determining the insulation status of the first electric path Z1 based on the measurement signal received from the first channel unit 110.

In case of monitoring the second electric path Z2, as shown in FIG. 7, the second switching portion 133-2 may connect the second channel unit 120 to the control unit 132 and the signal unit 131 may apply the predetermined signal to the ground PE, such that the second channel unit 120 may receive the measurement signal from the second electric path Z2 through the coupling device CL and the control unit 132 may receive the measurement signal from the second channel unit 120. Accordingly, the first insulation monitoring device 100 can determine the insulation status of the second electric path Z2 based on the measurement signal.

That is, when monitoring the second electric path Z2, as shown in FIG. 7, the control unit 132 may be connected to the second channel unit 120 and disconnected from the first channel unit 110, to monitor the insulation of the second electric path Z2 by determining the insulation status of the second electric path Z2 based on the measurement signal received from the second channel unit 120.

In this way, the control unit 132 which is connected to one of the first channel unit 110 and the second channel unit 120 and receives the measurement signal to determine the insulation status of one of the first electric path Z1 and the second electric path Z2 can calculate the magnitude of insulation resistance in an electric path corresponding to the connected channel unit based on the measurement signal and determine the insulation status of the electric path corresponding to the connected channel unit based on the magnitude of the insulation resistance.

When the first power conversion device 10 and the second power conversion device 20 are in operation, as shown in FIG. 8, the first switching portion 133-1 may disconnect the first channel unit 110 from the control unit 132 and the second switching unit 133-2 may disconnect the second channel unit 120 from the control unit 132, suppressing the first insulation monitoring device 100 from determining the insulation status of the first electric path Z1 and the second electric path Z2.

In this case, the second insulation monitoring device 200 may determine the insulation status of the first electric path Z1 in the first load-side electric path ZL-1, and the third insulation monitoring device 300 may determine the insulation status of the second electric path Z2 in the second load-side electric path ZL-2.

Meanwhile, when only the second power conversion device 20 is in operation, the first switching unit 133-1 may connect the first channel unit 110 to the control unit 132, such that the first insulation monitoring device 100 can determine the insulation status of the first electric path Z1.

In another example, when only the first power conversion device 10 is in operation, the second switching unit 133-2 may connect the second channel unit 120 to the control unit 132, such that the first insulation monitoring device 100 can determine the insulation status of the second electric path Z2.

The insulation monitoring device 1000 described above may be applied to the insulation monitoring device 100 according to the embodiment described above and an insulation monitoring method according to an embodiment to be described below, or may be implemented by applying the embodiments described above or embodiments to be described below, and may also be implemented independently of the embodiments described above or the embodiments to be described below.

### Insulation Monitoring Method

Hereinafter, an insulation monitoring method according to an embodiment will be described, but any part that overlaps the contents of the insulation monitoring device 100 and the insulation monitoring system 1000 described above will be omitted on the premise that the descriptions of the insulation monitoring device 100 and the insulation monitoring system 1000 are equally applicable.

An insulation monitoring method according to an embodiment, as shown in FIG. 5, may be an insulation monitoring method performed by the (first) insulation monitoring device 100, which includes the first channel unit 110 receiving a signal from the first electric path Z1 between the transformer 1 and the first power conversion device 10, the second channel unit 120 receiving a signal from the coupling device CL, which receives a signal from the second electric path Z2 between the transformer 1 and the second power conversion device 20, and the monitoring unit 130 applying the predetermined signal to the ground PE to which the first electric path Z1 and the second electric path Z2 are not connected, to determine the insulation status of one of the first electric path Z1 and the second electric path Z2 based on a signal received from one of the first channel unit 110 and the second channel unit 120.

The insulation monitoring method may be a method performed by the monitoring unit 130 of the insulation monitoring device 100.

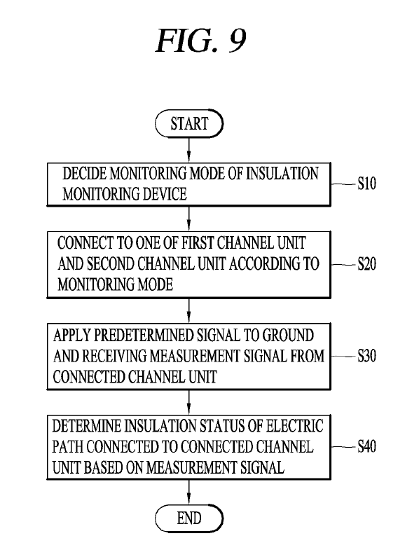

The insulation monitoring method includes, as shown in FIG. 9, deciding a monitoring mode of the insulation monitoring device 100 (S10), connecting to one of the first channel unit 110 and the second channel unit 120 according to the monitoring mode (S20), applying the predetermined signal to the ground PE to receive the measurement signal corresponding to the predetermined signal from the connected channel unit (S30), and determining an insulation status of an electric path connected to the connected channel unit based on the measurement signal (S40).

Here, the monitoring mode may be a mode for monitoring one of the first electric path Z1 and the second electric path Z2 while at least one of the first power conversion device 10 and the second power conversion device 20 is not in operation.

The monitoring mode may include, for example, a first mode for monitoring the first electric path Z1 and a second mode for monitoring the second electric path Z2.

The first mode may be a mode performed while the first power conversion device 10 is not in operation.

The second mode may be a mode performed while the second power conversion device 20 is not in operation.

The deciding step (S10) may be to decide the monitoring mode according to a signal received by the monitoring unit 130 from at least one of the first power conversion device 10 and the second power conversion device 20.

Here, the signal received from at least one of the first power conversion device 10 and the second power conversion device 20 may be a signal regarding an operating state of the first power conversion device 10 and the second power conversion device 20.

Accordingly, when the monitoring unit 130 receives a signal regarding a non-operating state from at least one of the first power conversion device 10 and the second power conversion device 20, the monitoring unit 130 may decide a mode for monitoring one of the first electric path Z1 and the second electric path Z2.

The connecting step (S20) may be to connect the monitoring unit 130 to one of the first channel unit 110 and the second channel unit 120 according to a result of the decision in the deciding step (S10).

The connecting step (S20) may be to connect the monitoring unit 130 to the first channel unit 110 when the monitoring mode is a mode for monitoring the first electric path Z1.

The connecting step (S20) may be to connect the monitoring unit 130 to the second channel unit 120 when the monitoring mode is a mode for monitoring the second electric path Z2.

The receiving step (S30) may be to receive the measurement signal from the channel unit connected in the connecting step (S20), in response to the monitoring unit 130 applying the predetermined signal to the ground PE.

The receiving step (S30) may be to receive the measurement signal from the first channel unit 110 when the monitoring mode is a mode for monitoring the first electric path Z1.

The receiving step (S30) may be to receive the measurement signal from the second channel unit 120 when the monitoring mode is a mode for monitoring the second electric path Z2.

The determining step (S40) may be to allow the monitoring unit 130 to determine the insulation status of the electric path connected to the connected channel unit based on the measurement signal received in the receiving step (S30).

The determining step (S40) may be to determine the insulation status of the first electric path Z1 based on the measurement signal received from the first channel unit 110 when the monitoring mode is the mode for monitoring the first electric path Z1.

The determining step (S40) may be to determine the insulation status of the second electric path Z2 based on the measurement signal received from the second channel unit 120 when the monitoring mode is the mode for monitoring the second electric path Z2.

The determining step (S40) may be to calculate magnitude of insulation resistance of the electric path connected to the connected channel unit based on the measurement signal, and determine the insulation status of the electric path connected to the connected channel unit based on the magnitude of the insulation resistance.

The insulation monitoring method described above can be implemented as computer-readable codes in a program-recorded medium.

Here, the computer-readable medium may include all types of recording devices, such as hard disk drive (HDD), solid state disk (SSD), silicon disk drive (SDD), ROM, RAM, CD-ROM, magnetic tape, floppy disk, optical data storage device, etc., in which data which is readable by a computer system is stored, and may also include those implemented in the form of a carrier wave (e.g., transmission via the Internet).

The computer may include the control unit 132 of the insulation monitoring device 100

So far, the embodiments of the insulation monitoring device 100, the insulation monitoring system 1000, and the insulation monitoring method have been described, but the described embodiments may be modified in various ways without departing from the scope of the disclosure, and the scope of the disclosure should not be limited to the described embodiments, but should be determined by the claims described below as well as equivalents of the claims.

What is claimed is:

1. An insulation monitoring device of monitoring insulation of a plurality of systems connected to a multi-winding transformer, the device comprising:
a first channel unit connected to an electric path of a first zone between the multi-winding transformer and a first power conversion device in a first system;
a second channel unit connected to a coupling device connected to an electric path of a second zone between the multi-winding transformer and a second power conversion device in a second system; and
a monitoring unit connected to a ground that is not connected to an electric path of the first system, connected to one of the first channel unit and the second channel unit according to an operation signal transmitted from at least one of the first power conversion device and the second power conversion device, and configured to apply a predetermined signal to one of the ground and a connected channel unit, receive a measurement signal corresponding to the predetermined signal from another channel unit, and determine an insulation status of a zone corresponding to the connected channel unit based on the measurement signal.

2. The insulation monitoring device of claim 1, wherein
a first protection device is arranged in the first zone to connect or disconnect the multi-winding transformer to or from the first power conversion device, and
the first channel unit is connected to an electric path between the multi-winding transformer and the first protection device.

3. The insulation monitoring device of claim 2, wherein
one of the first channel unit and the second channel unit is connected to the monitoring unit while the first protection device is open.

4. The insulation monitoring device of claim 1, wherein
a second protection device is arranged in the second zone to connect or disconnect the multi-winding transformer to or from the second power conversion device, and
the second channel unit is connected to an electric path between the multi-winding transformer and the second protection device.

5. The insulation monitoring device of claim 4, wherein
one of the first channel unit and the second channel unit is connected to the monitoring unit while the second protection device is open.

6. The insulation monitoring device of claim 1, wherein
the first channel unit and the second channel unit are disconnected from the monitoring unit in a state where a first protection device arranged in the first zone to connect or disconnect the multi-winding transformer to or from the first power conversion device and a second protection device arranged in the second zone to connect or disconnect the multi-winding transformer to or from the second power conversion device are closed.

7. The insulation monitoring device of claim 1, wherein
the monitoring unit is connected to the first channel unit to determine an insulation status of the first zone based on the measurement signal received from the ground or the first channel unit when receiving a first operation signal from at least one of the first power conversion device and the second power conversion device, and
connected to the second channel unit to determine an insulation status of the second zone based on the measurement signal received from the ground or the second channel unit when a second operation signal is received from at least one of the first power conversion device and the second power conversion device.

8. The insulation monitoring device of claim 1, wherein
the monitoring unit calculates magnitude of insulation resistance of a zone corresponding to the connected channel unit based on the measurement signal, and determines an insulation status of the zone corresponding to the connected channel unit based on the magnitude of the insulation resistance.

9. An insulation monitoring system comprising:
a multi-winding transformer configured to transmit a three-phase alternating current (AC) voltage;
a first power conversion device installed in a first system, and configured to receive the AC voltage from the multi-winding transformer and convert the AC voltage into a direct current (DC) voltage;
a second power conversion device installed in a second system, and configured to receive the AC voltage from the multi-winding transformer and convert the AC voltage into a DC voltage;
a first insulation monitoring device configured to monitor insulation of a first electric path as a primary side of the first power conversion device;
a coupling device configured to receive a signal from a second electric path as a primary side of the second power conversion device;
a second insulation monitoring device configured to monitor insulation of a first load-side electric path receiving the DC voltage from the first power conversion device; and
a third insulation monitoring device configured to monitor insulation of a second load-side electric path receiving the DC voltage from the second power conversion device,
wherein the first insulation monitoring device comprises:
a first channel unit configured to receive a signal from the first electric path;
a second channel unit configured to receive a signal, which is received from the second electric path, from the coupling device;
a signal unit configured to apply a predetermined signal to a ground not connected to the first system and the second system;
a control unit connected to one of the first channel unit and the second channel unit, and configured to receive a measurement signal corresponding to the predetermined signal from a connected channel unit, and determine an insulation status of an electric path corresponding to the connected channel unit based on the measurement signal; and
a connecting unit configured to connect the first channel unit to the control unit when monitoring the first electric path, and connect the second channel unit to the control unit when monitoring the second electric path.

10. The insulation monitoring system of claim 9, further comprising:
a first protection device configured to connect or disconnect the multi-winding transformer to or from the first power conversion device, and
a second protection device configured to connect or disconnect the multi-winding transformer to or from the second power conversion device,
wherein the first insulation monitoring device is connected to an electric path between the multi-winding transformer and the first protection device, and
the coupling device is connected to an electric path between the multi-winding transformer and the second protection device.

11. The insulation monitoring system of claim 10, wherein
the connecting unit disconnects the first channel unit and the second channel unit from the control unit when the first protection device connects the multi-winding transformer to the first power conversion device and the second protection device connects the multi-winding transformer to the second power conversion device.

12. The insulation monitoring system of claim 9, wherein
the connecting unit comprises:
a first switching portion configured to connect the first channel unit to the control unit when monitoring the first electric path, and disconnect the first channel unit from the control unit when monitoring the second electric path, the first load-side electric path, or the second load-side electric path; and
a second switching portion configured to connect the second channel unit to the control unit when monitoring the second electric path, and disconnect the second channel unit from the control unit when monitoring the first electric path, the first load-side electric path, or the second load-side electric path.

13. An insulation monitoring method of an insulation monitoring device comprising
a first channel unit configured to receive a signal from a first electric path between a multi-winding transformer and a first power conversion device,
a second channel unit configured to receive a signal from a coupling device that receives a signal from a second electric path between the multi-winding transformer and a second power conversion device, and
a monitoring unit configured to monitor an insulation status of one of the first electric path and the second electric path based on a signal received from one of the first channel unit and the second channel unit by applying a predetermined signal to a ground, to which the first electric path and the second electric path are not connected, the method comprising:
deciding a monitoring mode of the insulation monitoring device;
connecting to one of the first channel unit and the second channel unit according to the monitoring mode;
applying the predetermined signal to the ground to receive a measurement signal corresponding to the predetermined signal from a connected channel unit; and
determining an insulation status of an electric path connected to the connected channel unit based on the measurement signal.

14. The insulation monitoring method of claim 13, wherein
the monitoring mode is a mode for monitoring one of the first electric path and the second electric path while at least one of the first power conversion device and the second power conversion device is not in operation.

15. The insulation monitoring method of claim 14, wherein
the connecting step is to connect to the first channel unit when the monitoring mode is a mode for monitoring the first electric path, and
to connect to the second channel unit when the monitoring mode is a mode for monitoring the second electric path.
